(19) United States
(12) Patent Application Publication
(10) Pub. No.: US 2023/0052108 A1
(43) Pub. Date: Feb. 16, 2023

(54) SEMICONDUCTOR DEVICE

(71) Applicant: ROHM CO., LTD., (US)

(72) Inventors: Kenji HAMA, Kyoto-shi, Kyoto (JP); Yuji ISHIMATSU, Kyoto-shi, Kyoto (JP); Hideo HARA, Kyoto-shi, Kyoto (JP)

(21) Appl. No.: 17/792,364

(22) PCT Filed: Feb. 12, 2021
(86) PCT No.: PCT/JP2021/005346

§ 371 Date: Jul. 12, 2022

(30) Foreign Application Priority Data
Mar. 10, 2020 (JP) 2020-040872

(51) Int. Cl. H01L 23/498; H01L 23/00; H01L 25/16; H01L 23/31

(52) U.S. Cl. CPC H01L 23/49861; H01L 24/48; H01L 24/32; H01L 25/165; H01L 23/49811; H01L 23/49844; H01L 23/3121; H01L 24/73; H01L 2224/48229; H01L 2224/48245; H01L 2224/32227; H01L 2224/32238; H01L 2924/19043; H01L 2224/32245; H01L 2224/73265

(57) ABSTRACT

A semiconductor device includes a substrate, a conductive part, a controller module and a sealing resin. The substrate has a substrate obverse surface and a substrate reverse surface facing away from each other in a z direction. The conductive part is made of an electrically conductive material on the substrate obverse surface. The controller module is disposed on the substrate obverse surface and electrically connected to the conductive part. The sealing resin covers the controller module and at least a portion of the substrate. The conductive part includes an overlapping wiring trace having an overlapping portion overlapping with the electronic component as viewed in the z direction. The overlapping portion of the overlapping wiring trace is not electrically bonded to the controller module.

### TECHNICAL FIELD

The present disclosure relates to semiconductor devices.

### BACKGROUND ART

A various types of semiconductor devices are available, including those called intelligent power modules (IPMs). Such a semiconductor device includes a semiconductor chip, a controller chip for controlling the semiconductor chip, and a sealing resin covering the semiconductor chip and the controller chip (see Patent Document 1).

### Prior Art Document

Patent Document 1: JP-A-2020-4893

### SUMMARY OF THE INVENTION

### Problem to be Solved by the Invention

A controller chip receives and outputs a plurality of different control signals. To process a greater number of control signals, the control chip needs to be provided with a greater number of conduction paths. Although conduction paths are conventionally formed by metal leads, this practice may not be suitable for increasing the packaging density of a semiconductor device.

The present disclosure has been conceived in view of the circumstances described above and has an objective to provide a semiconductor device designed to achieve a higher packaging density.

### Means to Solve the Problem

A first aspect of the present disclosure provides a semiconductor device including: a substrate having a substrate obverse surface and a substrate reverse surface facing away from each other in a thickness direction; a conductive part made of an electrically conductive material on the substrate obverse surface; an electronic component disposed on the substrate obverse surface and electrically connected to the conductive part; and a sealing resin covering the electronic component and at least a portion of the substrate. The conductive part includes an overlapping wiring trace having an overlapping portion overlapping with the electronic component as viewed in the thickness direction. The overlapping portion of the overlapping wiring trace is not electrically bonded to the electronic component.

According to the semiconductor device described above, conduction paths to the electronic component is provided by the conductive part disposed on the substrate obverse surface. With this configuration, thinner conduction paths can be provided at a higher density than conduction paths provided by metal leads. In addition, the overlapping wiring trace is disposed to overlap with an electronic component as viewed in the thickness direction. With this configuration, a shorter conduction path can be provided than a conduction path that is routed around the electronic component, which leads to greater design flexibility. The packaging density of the semiconductor device can therefore be increased.

Other features and advantages of the present disclosure will become more apparent from detailed description given below with reference to the accompanying drawings.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view of the semiconductor device shown in FIG. 1, with a sealing resin shown transparent.

FIG. 4 is a bottom view of the semiconductor device shown in FIG. 1.

FIG. 5 is a sectional view taken along line V-V of FIG. 3.

FIG. 6 is an enlarged view showing a part of FIG. 3.

FIG. 7 is a sectional view taken along line VII-VII of FIG. 6.

FIG. 8 is a plan view of a substrate of the semiconductor device shown in FIG. 1.

FIG. 9 is a flowchart showing processing steps of one example of a method for manufacturing the semiconductor device shown in FIG. 1.

FIG. 10 is a sectional view of a semiconductor device according to a second embodiment of the present disclosure.

FIG. 11 is an enlarged sectional view showing a part of FIG. 10.

FIG. 12 is a plan view of a semiconductor device according to a third embodiment of the present disclosure, with a sealing resin shown transparent.

FIG. 13 is a sectional view of a semiconductor device according to a fourth embodiment of the present disclosure.

FIG. 14 is an enlarged sectional view showing a part of FIG. 13.

FIG. 15 is an enlarged sectional view showing a part of FIG. 13.

### MODE FOR CARRYING OUT THE INVENTION

With reference to the drawings, preferred embodiments of the present disclosure will be described.

In the present disclosure, unless otherwise specified, “an object A is formed on an object B” and “an object A is formed with/over an object B” are used to cover that “the object A is formed directly on the object B” and also “the object A is formed indirectly on the object B with another object interposed between the object A and the object B”. Similarly, unless otherwise specified, “an object A is disposed on an object A” and “an object A is disposed over an object A” are used to cover “the object A is disposed directly on an object B” and also “the object A is disposed indirectly on the object B with another object interposed between the object A and the object B”. Similarly, unless otherwise specified, “an object is located on an object B” is used to cover “the object A is located in contact with the object B” and “the object A is located indirectly on the object B with another object interposed between the object A and the object B”. In addition, unless otherwise specified, “an object A overlaps with an object B as viewed in a certain direction” is used to cover “the object A overlaps with the entirety of the object B” and “the object A overlaps with a portion of the object B”.

### <First Embodiment>

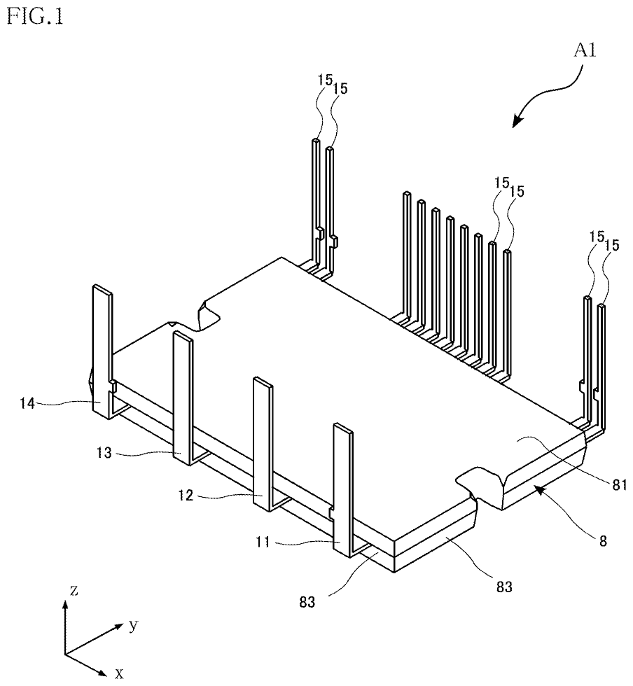

FIGS. 1 to 8 show a semiconductor device according to an embodiment of the present disclosure. The semiconductor device A1 of the present embodiment includes a plurality of leads 1, a substrate 2, a plurality of bonding parts 25, a conductive part 3, two semiconductor chips 4, two controller modules 5, and a plurality of passive elements 6, a plurality of wires 71, a plurality of wires 72 and a sealing resin 8. The semiconductor device A1 in this example is an intelligent power module (IPM). The semiconductor device A1 has uses in air conditioners and motor controller modules, for example.

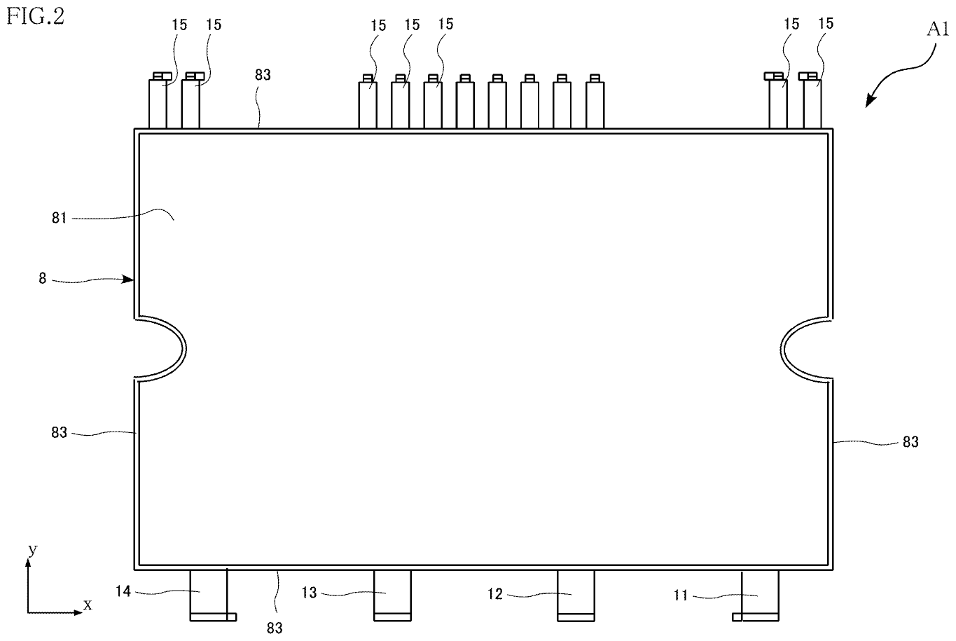

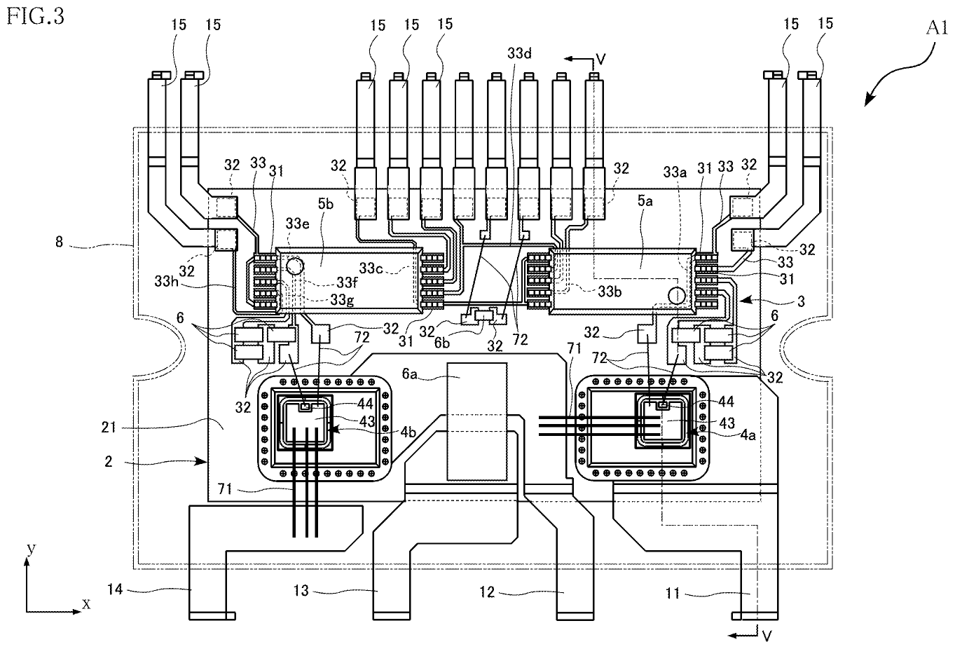

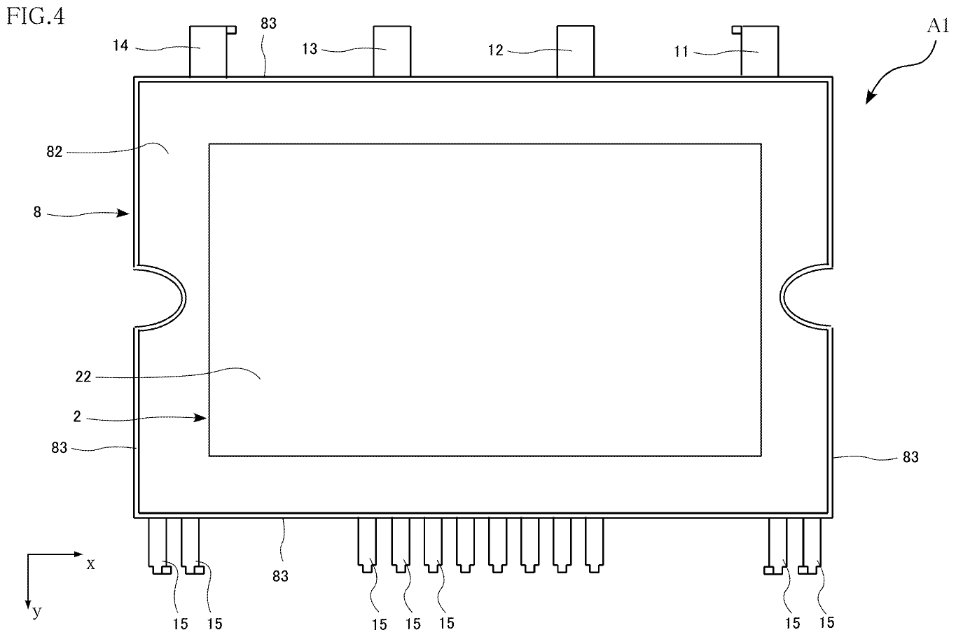

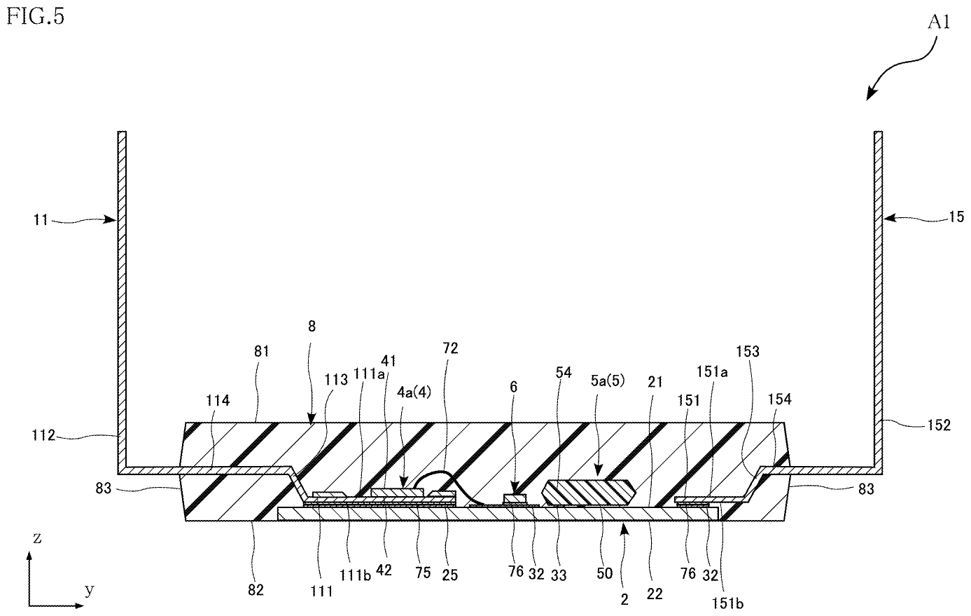

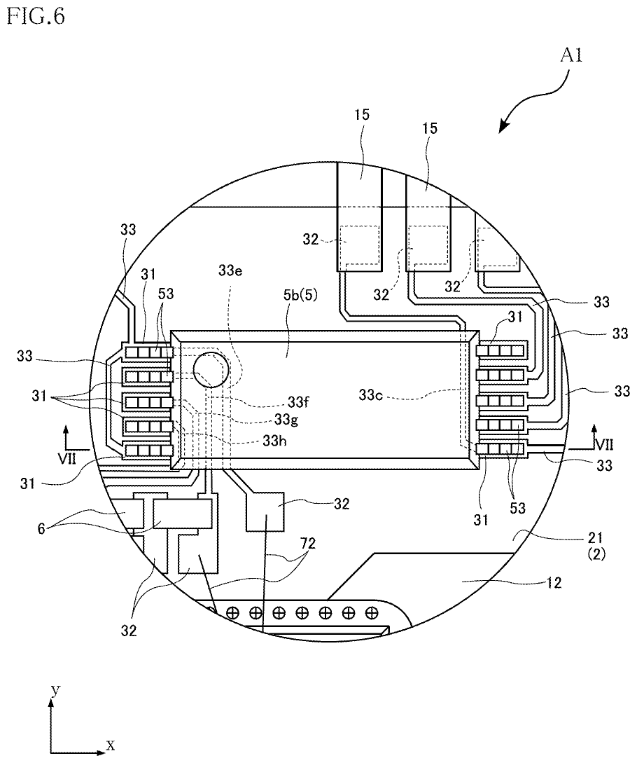

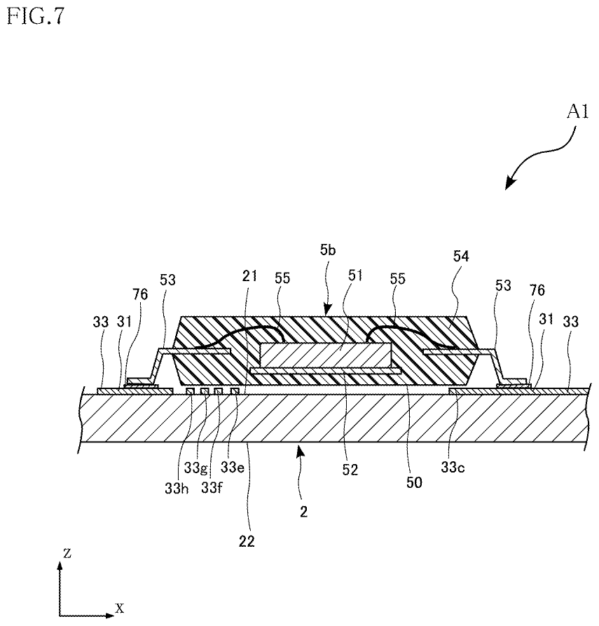

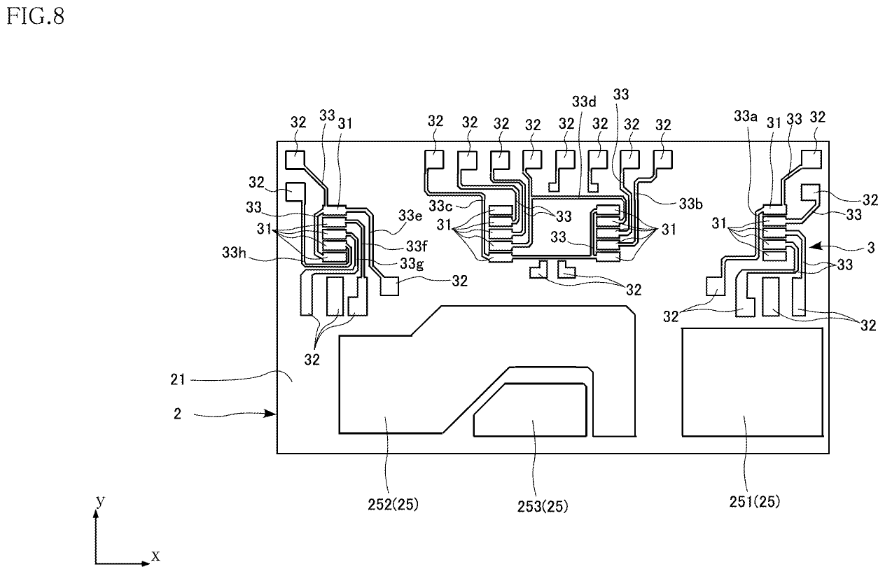

FIG. 1 is a perspective view of the semiconductor device A1. FIG. 2 is a plan view of the semiconductor device A1. FIG. 3 is a plan view of the semiconductor device A1, with the sealing resin 8 shown transparent. In FIG. 3, the outline of the sealing resin 8 is shown in phantom (in chain double-dashed lines). FIG. 4 is a bottom view of the semiconductor device A1. FIG. 5 is a sectional view taken along line V-V of FIG. 3. FIG. 6 is an enlarged view showing a part of FIG. 3. FIG. 7 is a sectional view taken along line VII-VII of FIG. 6. In FIG. 7, the sealing resin 8 is omitted. FIG. 8 is a plan view of the substrate 2.

For convenience, the thickness direction of the substrate 2 (the plan view direction) is defined as z direction, a direction perpendicular to the z direction along an edge of the substrate 2 (the horizontal direction in FIGS. 2 to 4) is defined as x direction, and the direction perpendicular to the z and y directions (the vertical direction in FIGS. 2 to 4) is defined as y direction. Note that the z direction is an example of the “thickness direction”.

The substrate 2 as viewed in the z direction has the shape of a rectangular plate elongated in the x direction. The thickness (z-direction dimension) of the substrate 2 may be about 0.1 to 1.0 mm. This thickness is cited only by way of example, and the dimensions of the substrate 2 are not specifically limited. The substrate 2 is made of an insulating material. Although the material of the substrate 2 is not specifically limited, materials having higher thermal conductivity than the material of the sealing resin 8 are preferable. For example, ceramic materials, such as alumina (Al₂O₃), silicon nitride (SiN), aluminum nitride, and zirconia alumina may be used for the substrate 2.

The substrate 2 has a substrate obverse surface 21 and a substrate reverse surface 22. The substrate obverse surface 21 and the substrate reverse surface 22 are flat surfaces facing away from each other in the z direction and lying perpendicular to the z direction. The substrate obverse surface 21 faces upward in FIG. 5. The substrate obverse surface 21 is the surface on which the conductive part 3 and the bonding parts 25 are formed and the leads 1 and a plurality of electronic components are mounted. The plurality of electronic components includes the two semiconductor chips 4, the two controller modules 5 and the passive elements 6. The substrate reverse surface 22 faces downward in FIG. 5. As shown in FIG. 4, the substrate reverse surface 22 is exposed from the sealing resin 8. Both of the substrate obverse surface 21 and the substrate reverse surface 22 are rectangular. Note, however, that the shape of the substrate 2 is not specifically limited.

The conductive part 3 is formed on the substrate 2. According to the present embodiment, the conductive part 3 is formed on the substrate obverse surface 21 of the substrate 2. The conductive part 3 is made of an electrically conductive material, which is not specifically limited. Examples of electrically conductive materials usable for the conductive part 3 include those containing silver (Ag), copper (Cu) or gold (Au). The following description assumes that the conductive part 3 contains silver. In another example, however, the conductive part 3 may contain copper instead of silver or may contain gold instead of silver or copper. Alternatively, the conductive part 3 may contain Ag-Pt or Ag-Pd. Although not limited, the conductive part 3 may be formed by firing a paste containing such a metal. Although not limited, the conductive part 3 may have a thickness of about 5 to 30 μm.

The conductive part 3 is not limited to a specific configuration. According to the present embodiment, the conductive part 3 includes a plurality of first pads 31, a plurality of second pads 32 and a plurality of connection wiring traces 33 as shown in FIG. 8. The first pads 31 may be rectangular pads to which the controller modules 5 are electrically bonded. Note that the shape of the first pads 31 is not specifically limited. The first pads 31 are spaced apart from each other. The second pads 32 may be rectangular pads to which leads 15 (described later), the semiconductor chips 4 and the passive elements 6 are electrically connected. That the shape of the second pads 32 is not specifically limited. The second pads 32 are spaced apart from each other. Each connection wiring trace 33 connects a first pads 31 to a second pads 32. One or more of the connection wiring traces 33 may be connected to two first pads 31. The first pads 31 and the second pads 32 may include those not connected to any connection wiring trace 33. Since each connection wiring trace 33 is connected to a first pad 31 to which a controller module 5 is electrically bonded, the connection wiring trace 33 is electrically connected to the controller module 5. The connection wiring trace 33, however, is not electrically bonded to the controller module 5 itself.

According to the present embodiment, some of the connection wiring traces 33 overlap with a controller module 5 as viewed in the z direction. Specifically, these connection wiring traces 33 are disposed between the substrate obverse surface 21 of the substrate 2 and the controller module 5. Such a connection wiring trace 33 having a portion overlapping with a controller module 5 is an example of the “overlapping wiring trace”.

According to the present embodiment, the connection wiring traces 33 include connection wiring traces 33a, 33b, 33c, 33d, 33e, 33f, 33g and 33h as shown in FIGS. 3 and 8. The connection wiring trace 33a overlaps with a controller module 5a (described later). The connection wiring trace 33a is connected to: a first pad 31 that is electrically bonded to the controller module 5a; and a second pad 32 that is electrically connected to a semiconductor chip 4a (described later) by a wire 72. The connection wiring trace 33b overlaps with the controller module 5a. The connection wiring trace 33b is connected to: a first pad 31 that is electrically bonded to the controller module 5a; and a second pad 32 that is electrically bonded to a lead 15. The connection wiring trace 33c overlaps with a controller module 5b (described later). The connection wiring trace 33c is connected to: a first pad 31 that is electrically bonded to the controller module 5b; and a second pad 32 that is electrically bonded to a lead 15. The connection wiring trace 33d overlaps with the controller module 5a. The connection wiring trace 33d is connected to: a first pad 31 that is electrically bonded to the controller module 5a; a first pad 31 that is electrically bonded to the controller module 5b; and a second pad 32 that is electrically bonded to a lead 15.

The connection wiring trace 33e overlaps with the controller module 5b. The connection wiring trace 33e is connected to: a first pad 31 that is electrically bonded to the controller module 5b; and a second pad 32 that is electrically connected to a semiconductor chip 4b (described later) by a wire 72. The connection wiring trace 33f overlaps with the controller module 5b. The connection wiring trace 33f is connected to: a first pad 31 that is electrically bonded to the controller module 5b; and a second pad 32 that is electrically connected to the semiconductor chip 4b by a wire 72 and electrically bonded to a passive element 6. The connection wiring trace 33g overlaps with the controller module 5b. The connection wiring trace 33g is connected to: a first pad 31 that is electrically bonded to the controller module 5b; and a second pad 32 that is electrically bonded to a passive element 6. The connection wiring trace 33h overlaps with the controller module 5b. The connection wiring trace 33h is connected to: a first pad 31 that is electrically bonded to the controller module 5b; and a second pad 32 that is electrically bonded to a lead 15. The layout and shapes of the connection wiring traces 33 described above are merely one example and without limitation.

The bonding parts 25 are formed on the substrate 2 as shown in FIG. 8. According to the present embodiment, the bonding parts 25 are located on the substrate obverse surface 21 closer to one edge of the substrate 2 outward in the y direction (lower edge in FIG. 8). The construction material of the bonding parts 25 is not specifically limited, and a material capable of bonding the substrate 2 and the leads 1 may be used. For example, the bonding parts 25 are made of an electrically conductive material, which is not specifically limited. Examples of electrically conductive materials usable for the bonding parts 25 include those containing silver (Ag), copper (Cu), or gold (Au). The following description assumes that the bonding parts 25 contain silver. That is, this example assumes that the bonding parts 25 contain the same electrically conductive material as the conductive part 3. In another example, however, the bonding parts 25 may contain copper instead of silver or may contain gold instead of silver or copper. Alternatively, the bonding parts 25 may contain Ag-Pt or Ag-Pd. Although not limited, the bonding parts 25 may be formed by firing a paste containing such a metal, similarly to the process of forming the conductive part 3. Although not limited, the bonding parts 25 may have a thickness of about 5 to 30 μm.

According to the present embodiment, the bonding parts 25 include bonding parts 251, 252 and 253 as shown in FIG. 8. The bonding part 251, 252 and 253 are spaced apart from each other. The bonding part 251 is located closer to an edge of the substrate 2 outward in the x direction (right edge in FIG. 8). The bonding parts 251 is where a lead 11 (described later) is bonded. The bonding part 253 is located at the central portion of the substrate 2 in the x direction as viewed in the z direction. The bonding part 253 is where a lead 13 (described later) is bonded. The bonding part 252 is shaped to surround the bonding part 251. The bonding part 252 is where a lead 12 (described later) is bonded. The shapes and layout of the bonding parts 251, 252 and 253 are not specifically limited.

The leads 1 contain metal and have higher thermal conductivity than, for example, the substrate 2. Metals usable for forming the leads 1 are not specifically limited, and examples include copper (Cu), aluminum, iron (Fe), oxygen-free copper, and alloys of such metals (for example, Cu-Sn alloy, Cu-Zr alloy and Cu-Fe alloy). The leads 1 may be plated with nickel (Ni). The leads 1 may be formed from a metal plate that is stamped by pressing a meal mold or that is patterned by etching. The process for forming the leads 1 is not specifically limited. The thickness of the leads 1 may be, but not limited to, about 0.4 to 0.8 mm. The leas 1 are spaced apart from each other.

According to the present embodiment, the leads 1 include the lead 11, the lead 12, the lead 13, a lead 14 and the leads 15. The leads 11, 12, 13 and 14 provide conduction paths to the semiconductor chips 4. The leads 15 provide conduction paths to the controller modules 5 or the passive elements 6.

The lead 11 is disposed on the substrate 2. According to the present embodiment, the lead 11 is disposed on the substrate obverse surface 21. The lead 11 is bonded to the corresponding bonding part 25 by a bonding material 75. The bonding material 75 is not specifically limited as long as it is capable of bonding the lead 11 to the bonding part 25. For effective transfer of heat from the lead 11 to the substrate 2, the bonding material 75 having higher thermal conductivity is preferred. For example, silver paste, copper paste, and solder may be used. Alternatively, the bonding material 75 may be an insulative material, such as epoxy-based resin or silicone-based resin. In addition, in an example in which the substrate 2 is not provided with bonding parts 25, the lead 11 may be bonded to the substrate 2.

The lead 11 is not limited to a specific configuration. For purposes of description, the lead 11 of the present embodiment is divided to a first portion 111, a second portion 112, a third portion 113 and a fourth portion 114 as shown in FIG. 5.

The first portion 111 has an obverse surface 111a and a reverse surface 111b. The obverse surface 111a and the reverse surface 111b are flat surfaces facing away from each other in the z direction and lying perpendicular to the z direction. The obverse surface 111a faces upward in FIG. 5. The semiconductor chip 4a is bonded to the obverse surface 111a. The reverse surface 111b faces downward in FIG. 5. The reverse surface 111b is bonded to the corresponding bonding part 25 by the bonding material 75. The third portion 113 and the fourth portion 114 are covered by the sealing resin 8. The third portion 113 connects the first portion 111 to the fourth portion 114. The fourth portion 114 connects the third portion 113 to the second portion 112. The second portion 112 connected from an end of the fourth portion 114 is a portion of the lead 11 protruding from the sealing resin 8. The second portion 112 extends in y direction away from the first portion 111. The second portion 112 is used to electrically connect the semiconductor device A1 to an external circuit, for example. In the illustrated example, the second portion 112 is bent in the z direction in which the obverse surface 111a of the first portion 111 faces.

The lead 12 is disposed on the substrate 2. According to the present embodiment, the lead 12 is disposed on the substrate obverse surface 21. The lead 12 is bonded to the corresponding bonding part 25 by the bonding material 75. The lead 12 is not limited to a specific configuration. According to the present embodiment, the configuration of the lead 12 is similar to the configuration of the lead 11. The semiconductor chip 4b is bonded to the lead 12.

The lead 13 is disposed on the substrate 2. According to the present embodiment, the lead 13 is disposed on the substrate obverse surface 21. The lead 13 is bonded to the corresponding bonding part 25 by the bonding material 75. The lead 13 is not limited to a specific configuration. According to the present embodiment, the configuration of the lead 13 is similar to the configuration to the lead 11. The lead 13 is not bonded to any semiconductor chip 4.

According to the present embodiment, the lead 14 is not disposed on the substrate 2 and hence does not include portions corresponding to the first portion 111 and the third portion 113 of the lead 11. Note, however, that the lead 14 is not limited to such a configuration.

The leads 15 are disposed on the substrate 2. According to the present embodiment, the leads 15 are disposed on the substrate obverse surface 21. Each lead 15 is bonded to a second pad 32 of the conductive part 3 by an electrically conductive bonding material 76. The electrically conductive bonding material 76 is not specifically limited as long as it is capable of physically bonding a lead 15 to a second pad 32 and thereby electrically connecting the lead 15 to the second pad 32. For example, silver paste, copper paste or solder may be used for the conductive bonding material 76.

The leads 15 are not limited to a specific configuration. For purposes of description, each lead 15 of the present embodiment is divided to a first portion 151, a second portion 152, a third portion 153 and a fourth portion 154 as shown in FIG. 5.

The first portion 151 has an obverse surface 151a and a reverse surface 151b. The obverse surface 151a and the reverse surface 151b are flat surfaces facing away from each other in the z direction and lying perpendicular to the z direction. The obverse surface 151a faces upward in FIG. 5. The reverse surface 151b faces downward in FIG. 5. The reverse surface 151b is bonded to a second pad 32 by the electrically conductive bonding material 76. The third portion 153 and the fourth portion 154 are covered by the sealing resin 8. The third portion 153 connects the first portion 151 to the fourth portion 154. The fourth portion 154 connects the third portion 153 to the second portion 152. The second portion 152 connected from an end of the fourth portion 154 is a portion of the lead 15 protruding from the sealing resin 8. The second portion 152 extends in the y direction away from the first portion 151. The second portion 152 is used to electrically connect the semiconductor device A1 to an external circuit, for example. In the illustrated example, the second portion 152 is bent in the z direction in which the obverse surface 151a of the first portion 151 faces.

Each of the two semiconductor chips 4 is disposed on a different lead 1. When a distinction is necessary, one of the two semiconductor chips 4 is referred to as a semiconductor chip 4a, and the other as a semiconductor chip 4b. Otherwise, they are simply referred to as the semiconductor chips 4. The type and function of the semiconductor chips 4 are not specifically limited. In the following example, the semiconductor chips 4 are power transistors that control electric power. Each semiconductor chip 4 may be a metal-oxide-semiconductor field-effect transistor (MOSFET) build on a silicon carbide (SiC} substrate. The semiconductor chip 4 may be a MOSFET built on a silicone (Si) substrate rather than an SiC substrate and include an IGBT element. In another example, the semiconductor chip 4 may be a MOSFET containing gallium nitride (GaN). According to the present embodiment, the semiconductor device A1 includes two semiconductor chips 4, which however is only one example. The number of semiconductor chips 4 to be included is not specifically limited.

Each semiconductor chip 4 has the shape of a rectangular plate as viewed in the z direction. The semiconductor chip 4 has an element obverse surface 41 and an element reverse surface 42 and includes a source electrode 43, a gate electrode 44 and a drain electrode 45. The element obverse surface 41 and the element reverse surface 42 face away from each other in the z direction. The element obverse surface 41 faces upward in FIG. 5, and the element reverse surface 42 faces downward in FIG. 5. As shown in FIG. 3, the source electrode 43 and the gate electrode 44 are disposed on the element obverse surface 41. The drain electrode 45 is disposed on the element reverse surface 42. Note that the shapes and layout of the source electrode 43, the gate electrode 44 and the drain electrode 45 are not specifically limited.

As shown in FIGS. 3 and 5, the semiconductor chip 4a is disposed on the lead 11. The semiconductor chip 4a is bonded to the lead 11 by an electrically conductive bonding material (not shown), with the element reverse surface 42 facing the lead 11 as shown in FIG. 5. That is, the drain electrode 45 of the semiconductor chip 4a is electrically connected to the lead 11 by the electrically conductive bonding material . For example, silver paste, copper paste or solder may be used for the electrically conductive bonding material . As shown in FIG. 3, in addition, the source electrode 43 of the semiconductor chip 4a is electrically connected to the lead 12 by wires 71. The wires 71 may be made of aluminum (Al) or copper (Cu), for example. The wires 71 are not limited as to the material, the wire diameter and the numbers to be provided. As shown in FIG. 3, the semiconductor chip 4b is disposed on the lead 12. The semiconductor chip 4b is bonded to the lead 12 by an electrically conductive bonding material (not shown), with the element reverse surface 42 facing the lead 12. That is, the drain electrode 45 of the semiconductor chip 4b is electrically connected to the lead 12 by the electrically conductive bonding material. As shown in FIG. 3, in addition, the source electrode 43 of the semiconductor chip 4b is electrically connected to the lead 14 by wires 71. In this way, the drain electrode 45 of the semiconductor chip 4a is connected to the source electrode 43 of the semiconductor chip 4b, forming a bridge circuit.

As shown in FIG. 3, the source electrode 43 and the gate electrode 44 of the semiconductor chip 4a are electrically connected to the controller module 5a by the wires 72 and the conductive part 3. The wires 72 may be made of gold (Au), silver (Ag) and aluminum (Al), for example. The wires 72 are not limited as to the material, the wire diameter and the numbers to be provided. The controller module 5a inputs a drive signal to the gate electrode 44 of the semiconductor chip 4a. The source electrode 43 and the gate electrode 44 of the semiconductor chip 4b are electrically connected to the controller module 5b by the wires 72 and the conductive part 3. The controller module 5b inputs a drive signal to the gate electrode 44 of the semiconductor chip 4b. When a direct current is applied between the lead 11 and the lead 14, a drive signal is input to the respective gate electrodes 44 of the semiconductor chips 4a and 4b. In response, a switching signal is output from the lead 12 at a voltage switched according to the drive signal.

The two controller modules 5 disposed on the substrate obverse surface 21 of the substrate 2 are used to control operation of the semiconductor chips 4. When a distinction is necessary, one of the two controller modules 5 is referred to as a controller module 5a, and the other as a controller module 5b. Otherwise, they are simply referred to as the controller modules 5. The controller module 5a controls operation of the semiconductor chip 4a, whereas the controller module 5b controls operation of the semiconductor chip 4b. As shown in FIG. 5, each controller module 5 is located between a corresponding semiconductor chip 4 and the relevant leads 15. As shown in FIG. 3, the controller module 5a overlaps with the semiconductor chip 4a as viewed in the y direction, and the controller module 5b with the semiconductor chip 4b. Note, however, that the layout of the controller modules 5a and 5b are not specifically limited.

As shown in FIG. 7, each controller module 5 has an opposing surface 50, a controller chip 51, a die pad 52, a plurality of leads 53, a resin 54 and a plurality of wires 55. The controller chip 51 is an integrated circuit for controlling operation of the corresponding semiconductor chip 4 and supplies a drive signal for driving the semiconductor chip 4. The die pad 52 and the leads 53 may be plate-like components made of copper (Cu), for example. The die pad 52 is where the controller chip 51 is mounted. The leads 53 are electrically connected to the controller chip 51 by the wires 55. The resin 54 covers the entire controller chip 51, the entire wires 55, and a portion of each lead 53. In one example, the resin 54 is an insulating material, such as an epoxy resin or silicone gel.

The leads 53 are provided at spaced intervals in the y direction along the opposite edges of the resin 54 in the x direction. Each lead 53 extends in the x direction, and a portion of the lead 53 protrudes form the resin 54. The protruding portions of the leads 53 are electrically bonded to the first pads 31 of the conductive part 3. According to the present embodiment, each controller module 5 is provided in a small outline package (SOP). Note, however, that the package type of the controller modules 5 is not limited to SOP. In a different example, the package type may be quad flat package (QFP), small outline J-lead package (SOJ), or even another package. Each lead 53 is bonded to a first pad 31 of the conductive part 3 by the electrically conductive bonding material 76.

The opposing surface 50 faces the substrate obverse surface 21 when the controller module 5 is disposed on the substrate 2. The entire opposing surface 50 is formed by the resin 54. According to the present embodiment, the connection wiring traces 33 include those overlapping with the controller module 5 as viewed in the z direction (overlapping wiring traces). The overlapping wiring traces are disposed between the substrate obverse surface 21 of the substrate 2 and the opposing surface of the controller module 5. The overlapping wiring traces are kept isolated from the controller chip 51 of the controller module 5 because the controller chip 51 is covered by the resin 54 and the opposing surface 50 is formed by the resin 54. In a case where the controller chip 51 is not included in the controller module 5 and directly disposed on the substrate 2, forming overlapping wiring traces are not applicable. In such a case, the connection wiring traces 33 need to be routed around the controller chip 51 to avoid contact with the controller chip 51.

In the present embodiment, the controller module 5 is an example of the “electronic component”, the controller chip 51 is an example of the “electronic element”, and the resin 54 is an example of the “insulating part”. The controller module 5 is not limited as to the size, shape and the number of leads to be provided with. The controller module 5 may include a plurality of controller chips 51 or include a circuit chip other than the controller chip 51.

The passive elements 6 are disposed on the substrate obverse surface 21 of the substrate 2, and some are electrically bonded to the conductive part 3 and some to the leads 1. Examples of the passive elements 6 include resistors, capacitors, coils and diodes. Specifically, the passive elements 6 include a shunt resistor 6a and a thermistor 6b.

The shunt resistor 6a is disposed to extend from the lead 12 to the lead 13 and electrically bonded to the lead 12 and the lead 13. The shunt resistor 6a allows a portion of current flowing through the lead 12 to be output from the lead 13. The thermistor 6b is electrically bonded to two second pads 32 of the conductive part 3. The two second pads 32 are electrically connected to different leads 15 each by a wire 72 and the conductive part 3. The thermistor 6b outputs an electric current proportional to the ambient temperature in response to application of voltage across the two leads 15.

The other passive elements 6 are electrically bonded to the second pads 32 of the conductive part 3 and hence electrically connected to the corresponding controller modules 5 via the connection wiring traces 33 and the first pads 31. The passive elements 6 are not limited as to the types, the layout and the numbers to be provided. In the present embodiment, the passive elements 6 are examples of the “second electronic component”.

The sealing resin 8 at least covers the semiconductor chips 4a and 4b, the controller modules 5a and 5b, the passive elements 6, the wires 71 and 72, a portion of each lead 1 and a portion of the substrate 2. The material of the sealing resin 8 is not specifically limited, and insulating materials such as epoxy resin and silicone gel may be used appropriately.

The sealing resin 8 has a resin obverse surface 81, a resin reverse surface 82 and four resin side surfaces 83. The resin obverse surface 81 and the resin reverse surface 82 are flat surfaces facing away from each other in the z direction and lying perpendicular to the z direction. The resin obverse surface 81 faces upward in FIG. 5, and the resin reverse surface 82 faces downward in FIG. 5. Each resin side surface 83 connects the resin obverse surface 81 and the resin reverse surface 82, and faces outward in the x or y direction. As shown in FIG. 4, the substrate reverse surface 22 of the substrate 2 is exposed on the resin reverse surface 82 of the sealing resin 8. As shown in FIG. 5, the substrate reverse surface 22 and the resin reverse surface 82 are flush with each other.

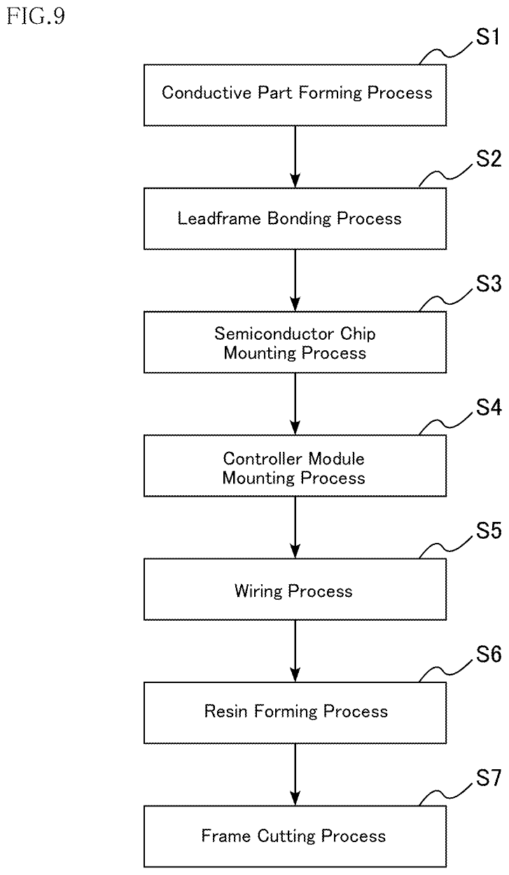

With reference to FIG. 9, an example of a method for manufacturing the semiconductor device A1 will be described. Note, however, the method for manufacturing the semiconductor device A1 is described merely by way of example and without limitation.

As shown in FIG. 9, the manufacturing method of this example includes a conductive part forming process (step S1), a leadframe bonding process (step S2), a semiconductor chip mounting process (step S3), a controller module mounting process (step S4), a wiring process (step S5), a resin forming process (step S6) and a frame cutting process (step S7).

The conductive part forming process (step S1) begins with preparing a substrate 2. The substrate 2 is made of a ceramic material, for example. Subsequently, a conductive part 3 and a plurality of bonding parts 25 are formed on the substrate obverse surface 21 of the substrate 2. In this example, the conductive part 3 and the bonding parts 25 are formed at a time. For example, printing of a metal paste followed by firing is performed to obtain the conductive part 3 and the bonding parts 25, which contain a conductive material metal such as silver (Ag).

The leadframe bonding process (step S2) begins with printing a bonding paste on the bonding parts 25 and printing an electrically conducting bonding paste on some of the second pads 32 of the conductive part 3. The bonding paste and the electrically conductive bonding paste may be a Ag paste or a solder paste, for example. Subsequently, a leadframe is prepared. The leadframe includes a plurality of leads 1 interconnected by a frame. The leadframe is not specifically limited as to the shape or other properties. Subsequently, the leads 11, 12 and 13 out of the plurality of leads 1 are placed facing the bonding parts 25 via the bonding paste. Also, the leads 15 out of the plurality of leads 1 are placed facing the conductive part 3 (the second pads 32) via the conductive bonding paste. Subsequently, by heating and then cooling the bonding paste and the conductive bonding paste, the bonding paste is formed into the bonding material 75, and the conductive bonding paste is formed into the electrically conductive bonding material 76. As a result, the leads 11, 12 and 13 are bonded to the bonding parts 25 by the bonding material 75, and the leads 15 are bonded to the conductive part 3 by electrically conductive bonding material 76.

The semiconductor chip mounting process (step S3) begins with printing an electrically conductive bonding paste on the predetermined regions of the lead 11 and the lead 12. The conductive bonding paste may be a Ag paste or a solder paste, for example. Subsequently, the semiconductor chip 4a is placed in contact with the conductive bonding paste printed on the lead 11, and the semiconductor chip 4b is placed in contact with the conductive bonding paste printed on the lead 11. Then, the conductive bonding paste is heated and then cooled, so that the conductive bonding paste is formed into the electrically conductive bonding material. As a result, the semiconductor chip 4a is bonded to the lead 11 by the electrically conductive bonding material , and the semiconductor chip 4b is bonded to the lead 12 by the electrically conductive bonding material. A similar process is performed to bond the shunt resistor 6a to the lead 11 and the lead 12 by the electrically conductive bonding material.

In the controller module mounting process (step S4), an electrically conductive bonding paste is printed on the first pads 31 of the conductive part 3. The conductive bonding paste may be a Ag paste or a solder paste, for example. Subsequently, the leads 53 of the controller modules 5a and 5b are placed in contact with the conductive bonding paste, and the conductive bonding paste is heated and then cooled. The resulting electrically conductive bonding material bonds the leads 53 of the controller modules 5a and 5b to the corresponding first pads 31. A similar process is performed to bond the thermistor 6b and the other passive elements 6 to the second pads 32 of the conductive part 3 by the electrically conductive bonding material.

The wiring process (step S5) begins with providing a plurality of wires 71. In this example, a wire made of aluminum (Al) is sequentially attached by, for example, wedge bonding. As a result, the wires 71 are provided. Next, a plurality of wires 72 are provided. In this example, a wire made of gold (Au) is sequentially attached by, for example, capillary wire bonding. As a result, the wires 72 are provided.

In the resin forming process (step S6), a metal mold is placed to surround a portion of the leadframe, a portion of the substrate 2, the semiconductor chips 4a and 4b, the controller modules 5a and 5b, the passive elements 6 and the wires 71 and 72. Subsequently, liquid resin is injected into the internal space of the metal mold. By curing the liquid resin, the sealing resin 8 is formed.

In the frame cutting process (step S7), the leadframe is appropriately cut at portions exposed from the sealing resin 8 to separate the interconnected leads 1. Then, the leads 1 go through necessary processing, such as bending. This completes the semiconductor device A1 described above.

Hereinafter, advantages of the semiconductor device A1 will be described below.

According to the present embodiment, the conductive part 3 is formed on the substrate obverse surface 21 of the substrate 2. The conductive part 3 includes the first pads 31 electrically bonded to the controller modules 5. In this way, conduction paths to the controller modules 5 are provided by the conductive part 3 formed on the substrate obverse surface 21. It is therefore possible to provide thinner conduction paths at a higher density than conduction paths provided by metal leads. The connection wiring traces 33 of the conductive part 3 include a traces overlapping with a controller module 5 as viewed in the z direction. The overlapping wiring trace can provide a shorter conduction path than a conduction path that is routed around the controller module 5, allowing greater flexibility in designing conduction paths. The packaging density of the semiconductor device A1 can therefore be increased.

According to the present embodiment, in addition, the controller chip 51 of each controller module 5 is covered by the resin 54, and the opposing surface 50 is formed by the resin 54. With this configuration, although some of the connection wiring traces 33 are disposed to overlap with the controller modules 5 in the z direction, the overlapping connection wiring traces are prevented from contacting the controller chips 51. This eliminates the need to form the connection wiring traces 33 in a manner to avoid overlap with the controller modules 5. Consequently, shorter conduction paths can be formed and the flexibility in designing conduction paths is increased.

According to the present embodiment, the controller modules 5 are used, and hence each controller chip 51 is covered by the resin 54. Suppose that the controller chip 51 is a bare chip not included in a controller module 5. Then, passing a high voltage and high current to the controller chip 51 is not possible. Therefore, a delivery inspection requiring passing such a current cannot be performed until the controller chip 51 is covered by the sealing resin 8 in a finished product. If the product is determined defective in the delivery inspection, the whole product needs to be discarded although the components other than the controller chip 51 may not be defective. In contrast, each controller module 5 includes the controller chip 51 already covered by the resin 54, so that a high voltage and high current can be passed for a delivery inspection. That is, the controller modules 5 can be inspected and defective products are discarded before they are mounted on semiconductor devices. In this way, the semiconductor device A1 can be fabricated using controller modules 5 having been determined non-defective, reducing the risk of wasting non-defective components.

According to the present embodiment, the leads 1 are more thermally conductive than the substrate 2, so that dissipation of heat from the semiconductor chips 4 which may be lowered by the presence of the substrate 2 can be improved. In addition, the semiconductor chip 4a is directly bonded to the lead 11, and the semiconductor chip 4b to the lead 12, both by the electrically conductive bonding material . The electrically conductive bonding material serves to electrically connect the semiconductor chip 4a (4b) to the lead 11 (12) and also to efficiently transfer heat from the semiconductor chip 4a (4b) to the lead 11 (12). In addition, the portions of leads 1 exposed from the sealing resin 8 are used to provide conduction paths for connecting an external component to the semiconductor chip 4 and also to improve the heat dissipation of the semiconductor chips 4. In addition, the substrate 2 has the bonding parts 25, and the leads 11, 12 and 13 are bonded to the substrate 2 at the bonding parts 25. The bonding parts 25 may have smoother surface finishing than the substrate obverse surface 21 of the substrate 2 made of a ceramic material. This is effective to prevent formation of undesirable voids in the heat conduction paths from the leads 11, 12 and 13 to the substrate 2, so that heat dissipation of, for example, the semiconductor chips 4 can be improved. In addition, the substrate reverse surface 22 of the substrate 2 is exposed from the sealing resin 8. This helps the substrate 2 to dissipate heat transferred from, for example, the semiconductor chips 4 to the outside.

According to the present embodiment, in addition, the conductive part 3 and the bonding parts 25 contain the same conductive material, allowing a batch processing of forming the conductive part 3 and the bonding parts 25 on the substrate 2. This helps to improve the efficiency of manufacturing the semiconductor device A1. The leads 15 are bonded to the second pads 32 of the conductive part 3 by the electrically conductive bonding material 76, ensuring that the leads 15 are fixed to the substrate 2 more firmly. The electrically conductive bonding material 76 also serves to reduce the resistance between the leads 15 and the conductive part 3.

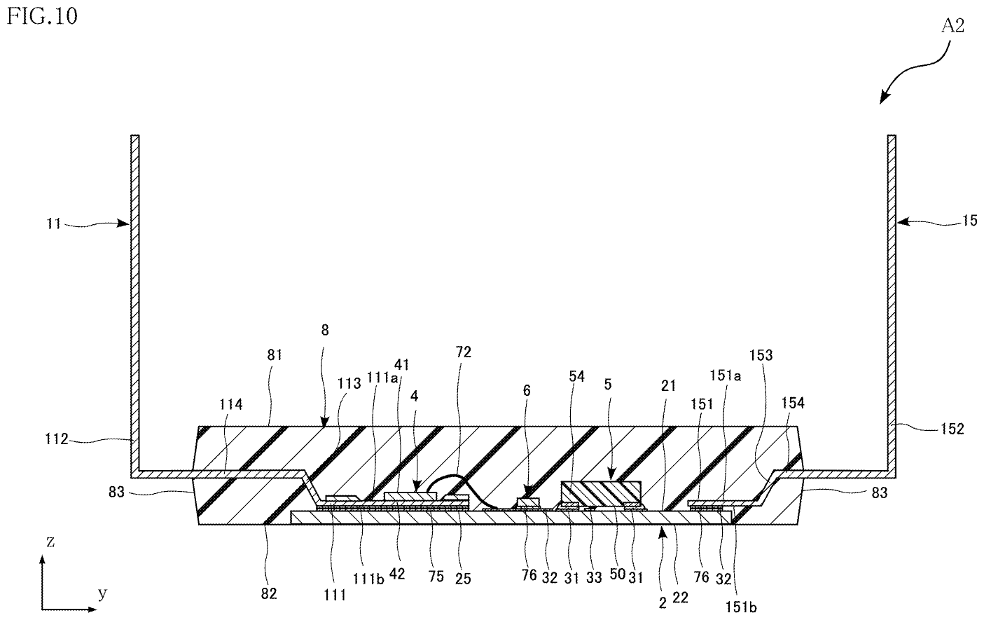

FIGS. 10 to 15 show other embodiments of the present disclosure. In these figures, the same or similar elements to those of the first embodiment are denoted by the same reference signs.

### <Second Embodiment>

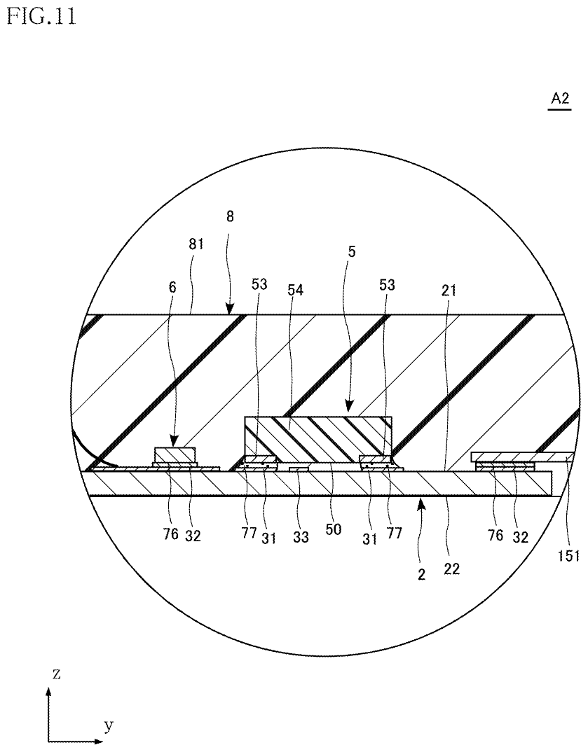

FIGS. 10 and 11 are views for illustrating a semiconductor device A2 according to a second embodiment of the present disclosure. FIG. 10 is a sectional view of the semiconductor device A2 and corresponds to FIG. 5. FIG. 11 is an enlarged sectional view showing a portion of FIG. 10. Unlike the first embodiment, the semiconductor device A2 of the present embodiment includes a controller module 5 that is a small outline non-leaded package (SON).

This embodiment includes a controller module 5 of a SON package. As shown in FIG. 11, the leads 53 do not protrude from the resin 54. Rather, the leads 53 are exposed on the bottom surface (the surface facing downward in FIG. 11) and the side surfaces (the surface perpendicular to the bottom surface) of the resin 54. The portions of the leads 53 exposed from the resin 54 are electrically bonded to the first pads 31 of the conducive part 3 by the electrically conductive bonding material 77. The electrically conductive bonding material 77 is not limited as long as it is capable of physically bonding a lead 53 to a first pad 31 and thereby electrically connecting the lead 53 to the first pad 31. For example, silver paste, copper paste or solder may be used for the electrically conductive bonding material 77. The controller module 5 has the opposing surface 50 including a portion formed by the resin 54 and a portion formed by the leads 53. According to the present embodiment, the connection wiring traces 33 include traces overlapping with the controller module 5 as viewed in the z direction (the overlapping wiring traces). The overlapping wiring traces are disposed to face the portion of the opposing surface 50 formed by the resin 54 but not the portion formed by the leads 53, avoiding contact with the leads 53. In the present embodiment, the portion of the opposing surface 50 formed by the resin 54 is an example of the “insulating part”.

According to the present embodiment, the connection wiring traces 33 of the conductive part 3 include a trace overlapping with the controller module 5 as viewed in the z direction. The overlapping wiring trace can provide a shorter conduction path than a conduction path that is routed around the controller module 5, allowing greater flexibility in designing conduction paths. The packaging density of the semiconductor device A2 can therefore be increased.

Note that the packaging of the controller module 5 is not limited to a SON package, and a different type of packaging, such as a quad flat non-leaded package (QFN), may be used. The controller module 5 of any packaging is applicable as long as at least a portion of the opposing surface 50 is formed by the resin 54.

### <Third Embodiment>

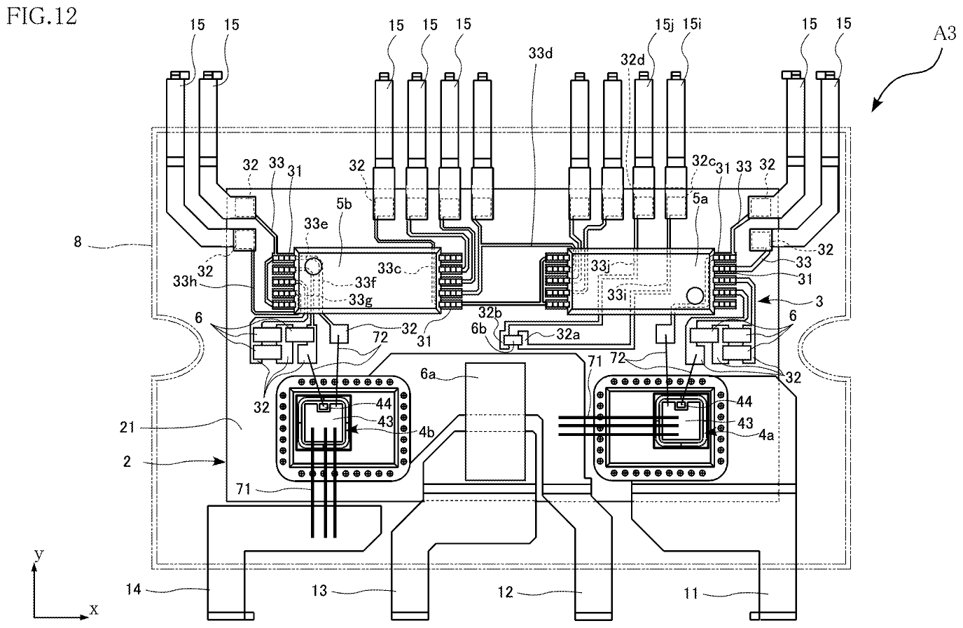

FIG. 12 is a view for illustrating a semiconductor device A3 according to a third embodiment of the present disclosure. FIG. 12 is a sectional view of the semiconductor device A3, with the sealing resin 8 shown transparent. This figure corresponds to FIG. 3. The semiconductor device A3 of the present embodiment is different from the first embodiment in the conduction paths from the thermistor 6b to the leads 15.

The thermistor 6b of the present embodiment is electrically bonded to a second pad 32a and a second pad 32b of the conductive part 3. The second pad 32a is electrically connected to a lead 15i via a connection wiring trace 33i and a second pad 32c. The second pad 32b is electrically connected to a lead 15j via a connection wiring trace 33j and a second pad 32d. The connection wiring traces 33i and 33j overlap with the controller module 5a as viewed in the z direction. The connection wiring traces 33i and 33j are electrically isolated from the controller module 5a. In short, the overlapping wiring traces of the present embodiment include the connection wiring traces 33i and 33j that are not electrically connected to the controller module 5a.

According to the present embodiment, the connection wiring traces 33 of the conductive part 3 include a trace overlapping with the controller module 5 as viewed in the z direction. The overlapping wiring trace can provide a shorter conduction path than a conduction path that is routed around the controller module 5, allowing greater flexibility in designing conduction paths. The packaging density of the semiconductor device A3 can therefore be increased.

### <Fourth Embodiment>

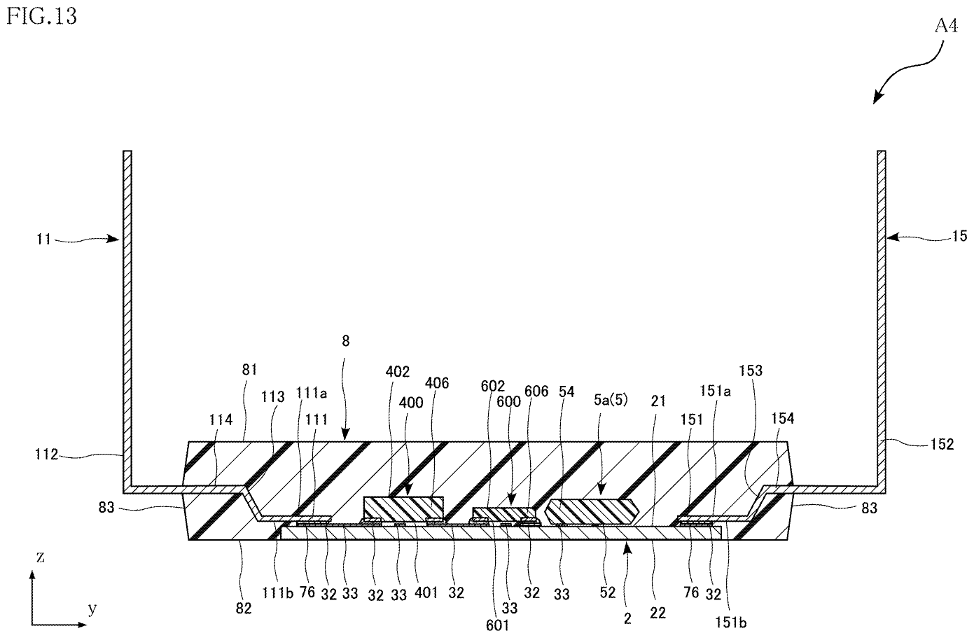

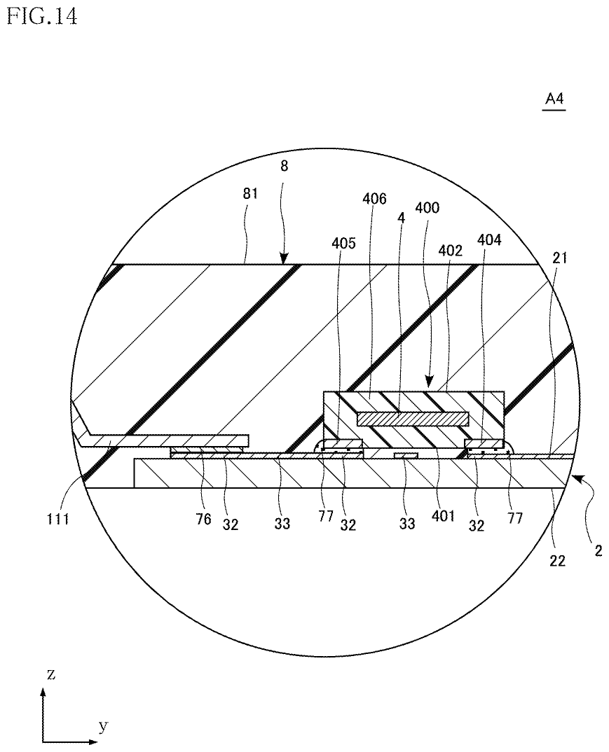

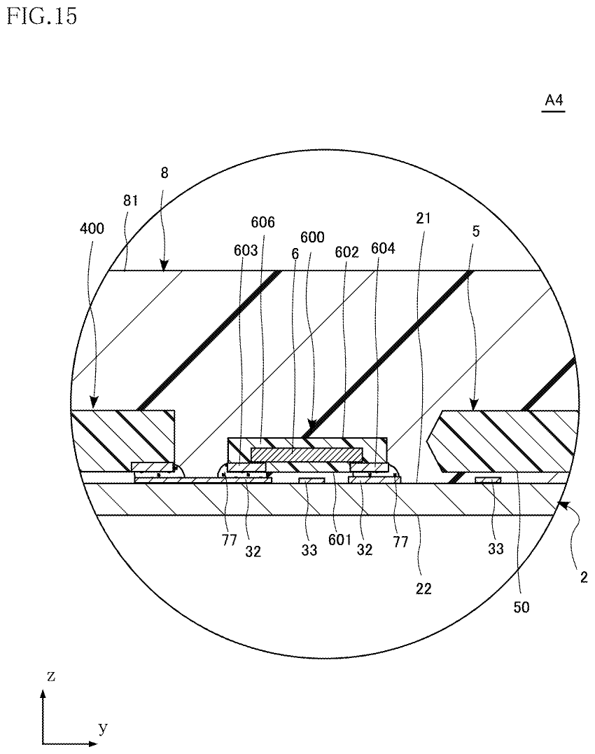

FIGS. 13, 14 and 15 are views for illustrating a semiconductor device A4 according to a fourth embodiment of the present disclosure. FIG. 13 is a sectional view of the semiconductor device A4 and corresponds to FIG. 5. FIGS. 14 and 15 are enlarged sectional views showing a portion of FIG. 13. Unlike the first embodiment, the semiconductor device A4 of the present embodiment includes semiconductor packages 400 instead of the semiconductor chips 4.

As shown in FIG. 13, the semiconductor device A4 of the present embodiment includes a semiconductor package 400 in place of a semiconductor chip 4. In the present embodiment, the conductive part 3 includes second pads 32 in place of the bonding parts 25. and the leads 11, 12 and 13 are electrically bonded to such second pads 32. The semiconductor package 400 is electrically bonded to the second pad 32 that is electrically connected to the lead 11 (12).

The semiconductor package 400 is a package assembled by sealing a semiconductor chip 4 with resin. As shown in FIG. 14, the semiconductor package 400 has an obverse surface 401, a reverse surface 402, the semiconductor chip 4, a source terminal 403, a gate terminal 404, a drain terminal 405 and a resin 406. The obverse surface 401 and the reverse surface 402 face away from each other in the z direction. The obverse surface 401 faces downward in FIGS. 13 and 14. The reverse surface 402 faces upward in FIGS. 13 and 14. The resin 406 covers the entire semiconductor chip 4 and a portion of each of the source terminal 403, the gate terminal 404 and the drain terminal 405. The resin 406 may be made of an insulating material, such as epoxy resin or silicone gel, for example. The source terminal 403, the gate terminal 404 and the drain terminal 405 are exposed on the obverse surface 401 from the resin 406. That is, the obverse surface 401 of the semiconductor package 400 has a portion formed by the resin 406 and portions formed by the source terminal 403, the gate terminal 404 and the drain terminal 405. In FIGS. 13 and 14, the conduction paths within the semiconductor package 400 are omitted. In addition, the source terminal 403 is not visible in FIGS. 13 and 14. Within the semiconductor package 400, the source terminal 403 is electrically connected to the source electrode 43 of the semiconductor chip 4, the gate terminal 404 to the gate electrode 44 of the semiconductor chip 4, and the drain terminal 405 to the drain electrode 45 of the semiconductor chip 4. The internal structure of the semiconductor package 400 is not specifically limited. The semiconductor package 400 may include a plurality of semiconductor chips 4 and/or another electronic component.

The semiconductor package 400 is disposed on the substrate obverse surface 21 with the obverse surface 401 facing toward the substrate 2. The source terminal 403, the gate terminal 404 and the drain terminal 405 are electrically bonded to the second pads 32 of the conductive part 3 by the electrically conductive bonding material 77. As shown in FIG. 14, the present embodiment includes a connection wiring traces 33 overlapping with the semiconductor package 400 as viewed in the z direction. The connection wiring trace (overlapping wiring trace) is located between the substrate obverse surface 21 of the substrate 2 and the obverse surface 401 of the semiconductor package 400. The overlapping wiring trace is disposed only at a location opposite the portion of the obverse surface 401 formed by the resin 406 to avoid unwanted contact with the source terminal 403, the gate terminal 404 and the drain terminal 405. In the present embodiment, the semiconductor package 400 is an example of an “electronic component”, the semiconductor chip is an example of an “electronic element”. In addition, the portion of the obverse surface 401 formed with the resin 406 is an example of an “insulating part”. The semiconductor device A4 may include one or more semiconductor packages 400 but no unpackaged semiconductor chips 4 or include both the packaged and unpackaged semiconductor chips 4.

The semiconductor device 4 includes a passive element package 600 instead of a passive element 6. The passive element package 600 is a package assembled by sealing the passive element 6 with resin. As shown in FIG. 15, the passive element package 600 has an obverse surface 601, a reverse surface 602, the passive element 6, terminals 603 and 604, and a resin 606. The obverse surface 601 and the reverse surface 602 face away from each other in the z direction. The obverse surface 601 faces downward in FIGS. 13 and 15. The reverse surface 602 faces upward in FIGS. 13 and 15. The resin 606 covers the entire passive element 6 and a portion of each of the terminals 603 and 604. The resin 606 may be made of an insulating material, such as epoxy resin or silicone gel, for example. The terminals 603 and 604 are exposed on the obverse surface 601 from the resin 606. That is, the obverse surface 601 of the passive element package 600 includes a portion formed by the resin 606 and portions formed by the terminals 603 and 604. The terminals 603 and 604 are electrically connected to the electrodes of the passive element 6 within the passive element package 600. The internal structure of the passive element package 600 is not specifically limited. For example, the passive element package 600 may include a plurality of passive elements 6.

The passive element package 600 is disposed on the substrate obverse surface 21 with the obverse surface 601 facing toward the substrate 2. Each of the terminals 603 and 604 is electrically bonded to a second pad 32 of the conductive part 3 by the electrically conductive bonding material 77. As shown in FIG. 15, the present embodiment includes a connection wiring trace 33 overlapping with the passive element package 600 as viewed in the z direction. The connection wiring trace (overlapping wiring trace) is located between the substrate obverse surface 21 of the substrate 2 and the obverse surface 601 of the passive element package 600. The overlapping wiring trace is disposed only at a location opposite the portion of the obverse surface 601 formed by the resin 606 to avoid unwanted contact with the terminals 603 and 604. In the present embodiment, the passive element package 600 is an example of an “electronic component” and the passive element is an example of an “electronic element”. In addition, the portion of the obverse surface 601 formed with the resin 606 is an example of an “insulating part”. The semiconductor device A4 may include one or more passive element packages 600 but no unpackaged passive elements 6 or include both the packaged and unpackaged passive elements 6.

According to the present embodiment, the connection wiring traces 33 of the conductive part 3 include a trace overlapping with the semiconductor package 400 or the passive element package 600 as viewed in the z direction. The overlapping wiring trace can provide a shorter conduction path than a conduction path that is routed around the semiconductor package 400 and the passive element package 600, allowing greater flexibility in designing conduction paths. The packaging density of the semiconductor device A4 can therefore be increased.

The semiconductor device A4 may be configured without either or a semiconductor package 400 and the passive element package 600. In addition, the semiconductor device A4 may include a controller chip 51 not packaged as a controller module 5.

The semiconductor devices according to the present disclosure are not limited to the embodiments described above. Various design changes can be made to the specific details of the elements or components of the semiconductor devices according to the present disclosure. The present disclosure relates to any semiconductor device provided with a conductive part 3 formed on a substrate obverse surface 21 of a substrate 2, an electronic component disposed on conductive part 3, and a connection wiring trace 33 overlapping with the electronic component as viewed in the z direction.

### [Clause 1]

A semiconductor device comprising:

a substrate having a substrate obverse surface and a substrate reverse surface facing away from each other in a thickness direction;

a conductive part made of an electrically conductive material on the substrate obverse surface;

an electronic component disposed on the substrate obverse surface and electrically connected to the conductive part; and

a sealing resin covering the electronic component and at least a portion of the substrate,

wherein the conductive part includes an overlapping wiring trace having an overlapping portion that overlaps with the electronic component as viewed in the thickness direction, the overlapping portion being not electrically bonded to the electronic component.

### [Clause 2]

The semiconductor device according to Clause 1, wherein the electronic component has an opposing surface disposed opposite the substrate obverse surface, the opposing surface including an insulating portion made of an insulating material, and the overlapping wiring trace overlaps with the electronic component only at the insulating portion of the opposing surface as viewed in the thickness direction.

### [Clause 3]

The semiconductor device according to Clause 2, wherein an entire surface of the opposing surface is the insulating portion.

### [Clause 4]

The semiconductor device according to Clause 2 or 3, wherein the electronic component includes an electronic element and a resin covering the electronic element, and

the insulating portion is formed by a portion of the resin.

### [Clause 5]

The semiconductor device according to Clause 4, wherein the electronic element comprises a passive element.

### [Clause 6]

The semiconductor device according to Clause 4, wherein the electronic element comprises a switching element.

### [Clause 7]

The semiconductor device according to Clause 4, wherein the electronic element comprises a controller chip configured to output a drive signal.

### [Clause 8]

The semiconductor device according to any one of Clauses 1 to 7, further comprising:

a first lead disposed on the substrate obverse surface and having a higher thermal conductivity than the substrate; and

a semiconductor chip disposed on the first lead.

### [Clause 9]

The semiconductor device according to Clause 8, further comprising a bonding part formed on the substrate obverse surface, the bonding part containing a same electrically conductive material as the electrically conductive material of the conductive part,

wherein the first lead is bonded to the bonding part by a bonding material.

### [Clause 10]

The semiconductor device according to Clause 8 or 9, wherein the first lead has a portion covered by the sealing resin and another portion exposed from the sealing resin.

### [Clause 11]

The semiconductor device according to any one of Clauses 8 to 10, further comprising a second lead spaced apart from the first lead and bonded to the conductive part by an electrically conductive bonding material,

wherein the second lead has a portion covered by the sealing resin and another portion exposed from the sealing resin.

### [Clause 12]

The semiconductor device according to Clause 11, wherein the conductive part includes:

a first pad electrically bonded to the electronic component; and

a second pad electrically bonded to the second lead, and

the overlapping wiring trace is connected to the first pad and the second pad.

### [Clause 13]

The semiconductor device according to any one of Clauses 8 to 11, wherein the conductive part includes:

a first pad electrically bonded to the electronic component; and

a second pad electrically connected to the semiconductor chip, and

the overlapping wiring trace is connected to the first pad and the second pad.

### [Clause 14]

The semiconductor device according to any one of Clauses 8 to 11, further comprising a second electronic component disposed on the substrate obverse surface and electrically connected to the conductive part,

wherein the conductive part includes:

a first pad electrically bonded to the electronic component; and

a second pad electrically bonded to the second electronic component, and

the overlapping wiring trace is connected to the first pad and the second pad.

### [Clause 15]

The semiconductor device according to any one of Clauses 8 to 11, wherein the overlapping wiring trace is electrically isolated from the electronic component.

### [Clause 16]

The semiconductor device according to any one of Clauses 8 to 15, wherein the semiconductor chip comprises a power transistor that controls electric power.

### [Clause 17]

The semiconductor device according to any one of Clauses 8 to 16, wherein the semiconductor chip includes a reverse electrode bonded to the first lead.

### [Clause 18]

The semiconductor device according to any one of Clauses 1 to 17, wherein the substrate reverse surface is exposed from the sealing resin.

### [Clause 19]

The semiconductor device according to any one of Clauses 1 to 18, wherein the substrate is made of a ceramic material.

### Reference Sign List

A1, A2, A3, A4: Semiconductor Device
1, 11-15, 15i, 15j: Lead
111: First Portion
111a: Obverse Surface
111b: Reverse Surface
112: Second Portion
113: Third Portion
114: Fourth Portion
151: First Portion
151a: Obverse Surface
151b: Reverse Surface
152: Second Portion
153: Third Portion
154: Fourth Portion
2: Substrate
21: Substrate Obverse Surface
22: Substrate Reverse Surface
25, 251 to 253: Bonding Part
3: Conductive Part
31: First Pad
32,32a-32d: Second Pad
33, 33a-33d: Connection Wiring Trace
4, 4a, 4b: Semiconductor Chip
41: Obverse Surface
42: Reverse Surface
43: Source Electrode
44: Gate Electrode
45: Drain Electrode
5, 5a, 5b: Controller Module
50: Opposing Surface
51: Controller Chip
52: Die Pad
53: Lead
55: Wire
6: Passive Element
6a: Shunt Resistor
6b: Thermistor
71: Wire
72: Wire
75: Bonding Material
76, 77: Electrically Conductive Bonding Material
8: Sealing Resin
81: Resin Obverse Surface
82: Resin Reverse Surface
83: Resin Side Surface
400: Semiconductor Package
401: Obverse Surface
402: Reverse Surface
403: Source Terminal
404: Gate Terminal
405: Drain Terminal
600: Passive Element Package
601: Obverse Surface
602: Reverse Surface
603, 604: Terminal

1. A semiconductor device comprising:
a substrate having a substrate obverse surface and a substrate reverse surface facing away from each other in a thickness direction;
a conductive part made of an electrically conductive material on the substrate obverse surface;
an electronic component disposed on the substrate obverse surface and electrically connected to the conductive part; and
a sealing resin covering the electronic component and at least a portion of the substrate,
wherein the conductive part includes an overlapping wiring trace having an overlapping portion that overlaps with the electronic component as viewed in the thickness direction, and the overlapping portion being not electrically bonded to the electronic component.

2. The semiconductor device according to claim 1, wherein the electronic component has an opposing surface disposed opposite the substrate obverse surface, the opposing surface including an insulating portion made of an insulating material, and
the overlapping wiring trace overlaps with the electronic component only at the insulating portion of the opposing surface as viewed in the thickness direction.

3. The semiconductor device according to claim 2, wherein an entire surface of the opposing surface is the insulating portion.

4. The semiconductor device according to claim 2, wherein the electronic component includes an electronic element and a resin covering the electronic element, and
the insulating portion is formed by a portion of the resin.

5. The semiconductor device according to claim 4, wherein the electronic element comprises a passive element.

6. The semiconductor device according to claim 4, wherein the electronic element comprises a switching element.

7. The semiconductor device according to claim 4, wherein the electronic element comprises a controller chip configured to output a drive signal.

8. The semiconductor device according to claim 1, further comprising:
a first lead disposed on the substrate obverse surface and having a higher thermal conductivity than the substrate; and
a semiconductor chip disposed on the first lead.

9. The semiconductor device according to claim 8, further comprising a bonding part formed on the substrate obverse surface, the bonding part containing a same electrically conductive material as the electrically conductive material of the conductive part,
wherein the first lead is bonded to the bonding part by a bonding material.

10. The semiconductor device according to claim 8, wherein the first lead has a portion covered by the sealing resin and another portion exposed from the sealing resin.

11. The semiconductor device according to claim 8, further comprising a second lead spaced apart from the first lead and bonded to the conductive part by an electrically conductive bonding material,
wherein the second lead has a portion covered by the sealing resin and a portion exposed from the sealing resin.

12. The semiconductor device according to claim 11, wherein the conductive part includes:
a first pad electrically bonded to the electronic component; and
a second pad electrically bonded to the second lead, and
the overlapping wiring trace is connected to the first pad and the second pad.

13. The semiconductor device according to claim 8, wherein the conductive part includes:
a first pad electrically bonded to the electronic component; and
a second pad electrically connected to the semiconductor chip, and
the overlapping wiring trace is connected to the first pad and the second pad.

14. The semiconductor device according to claim 8, further comprising a second electronic component disposed on the substrate obverse surface and electrically connected to the conductive part,
wherein the conductive part includes:
a first pad electrically bonded to the electronic component; and
a second pad electrically bonded to the second electronic component, and
the overlapping wiring trace is connected to the first pad and the second pad.

15. The semiconductor device according to claim 8, wherein the overlapping wiring trace is electrically isolated from the electronic component.

16. The semiconductor device according to claim 8, wherein the semiconductor chip comprises a power transistor that controls electric power.

17. The semiconductor device according to claim 8, wherein the semiconductor chip includes a reverse electrode bonded to the first lead.

18. The semiconductor device according to claim 1, wherein the substrate reverse surface is exposed from the sealing resin.

19. The semiconductor device according to claim 1, wherein the substrate is made of a ceramic material.
